(19) United States
(12) Patent Application Publication
(10) Pub. No.: US 2016/0276142 A1
(43) Pub. Date: Sep. 22, 2016

(54) SUBSTRATE CARRIER FOR A REDUCED TRANSMISSION OF THERMAL ENERGY

(71) Applicant: Applied Materials, Inc., Santa Clara, CA (US)

(72) Inventors: Andreas Ewald LOPP, Freigericht (DE); Stefan KELLER, Mainaschaff (DE); Uwe SCHÜßLER, Aschaffenburg (DE); Stefan BANGERT, Steinau (DE); Thomas GEBELE, Freigericht (DE); Norbert SPATZ, Mespelbrunn (DE)

(21) Appl. No.: 15/031,138

(22) PCT Filed: Nov. 25, 2013
(86) PCT No.: PCT/EP2013/074604

§ 371 Date: Apr. 21, 2016

(51) Int. Cl. H01J 37/32; C23C 16/458; C23C 14/50; H01L 21/673

(52) U.S. Cl. CPC H01J 37/32724; H01L 21/67316; C23C 16/4581; C23C 14/50; H01L 31/1876

(57) ABSTRACT

According to the present disclosure, a semiconductor substrate handling systems and substrate carrier is provided. The substrate carrier for holding a substrate to be processed and for transporting the substrate in or through a processing area with a transport device includes a main portion for holding the substrate; a first end portion adapted to be supported by the transport device; and at least one first intermediate portion connecting the main portion with the first end portion. The at least one first intermediate portion includes one or more cut-outs adapted to reduce thermal energy transfer between the main portion and the first end portion.

### FIELD OF THE INVENTION

The subject-matter described herein generally relates to substrate handling systems and, more particularly, to substrate carriers and systems for processing substrates during material deposition processes used in the thin film battery production and display industry.

### BACKGROUND OF THE INVENTION

Generally, substrate carriers are used for supporting or holding substrates or wafers to be processed and for transporting them in or through processing facilities. For instance, substrate carriers are used in the display or photovoltaic industry for transporting substrates or wafers including glass, silicon or other materials in or through processing facilities. Such substrate supports or substrate carriers may be vital, in particular, if the substrates or wafers are particularly thin with a large surface area, such that direct transport thereof, i.e. transport without using auxiliary transport devices, is not possible due to the risk of damage.

For example, in physical vapor deposition (PVD) processes such as sputtering, the substrate carriers generally provide relatively planar surfaces, which keep substrates leveled during the material deposition processes.

One of the drawbacks associated with substrate carriers or holders is their proneness to warping during high temperature processing. Minute deformations of the carrier due to, for instance, thermal expansion may result in an uneven deposition of the material on the substrate. This inhomogeneous material deposition may substantially impact the deposition quality. Hence, during high temperature processing substrate carriers may be used that include materials such as graphite, which are more temperature stable. However, these materials are typically very expensive, resulting in the total cost of ownership (TCO) of such substrate handling systems, e.g. for thin film battery manufacturing, display manufacturing, or other applications, being relatively high.

For this purpose, it will be appreciated that a substrate carrier and a substrate handling systems with a reduced TCO and improved stability during high temperature deposition processes is desired. Hence, the subject-matter described herein pertains to improved substrate carriers or substrate holders and substrate handling systems that allow deposition of layers of materials on substrates with high quality and at low operational costs.

### BRIEF DESCRIPTION OF THE INVENTION

In one aspect, a substrate carrier for holding a substrate to be processed and for transporting the substrate in or through a processing area with a transport device is provided. The substrate carrier includes a main portion for holding the substrate; a first end portion adapted to be supported by the transport device; and at least one first intermediate portion connecting the main portion with the first end portion. The at least one first intermediate portion includes one or more cut-outs adapted to reduce thermal energy transfer between the main portion and the first end portion.

In another aspect, a use of the substrate carrier as described above is provided for reducing the thermal energy transfer between a substrate and a transport device whilst the substrate held by the substrate carrier is undergoing thermal processing.

In yet another aspect, a system for processing a substrate is provided. The system includes a substrate carrier as described above; at least one processing chamber for processing the substrate; and a transport device for supporting the substrate carrier.

Further aspects, advantages and features of the present invention are apparent from the dependent claims, the description and the accompanying drawings.

### BRIEF DESCRIPTION OF THE DRAWINGS

A full and enabling disclosure including the best mode thereof, to one of ordinary skill in the art, is set forth more particularly in the remainder of the specification, including reference to the following accompanying Figs.:

FIG. 1 is a schematic representation according to embodiments herein showing a substrate carrier for holding a substrate.

FIG. 2 is a schematic representation according to embodiments herein showing a cross-section of the substrate carrier shown in FIG. 1 along line A-A.

FIG. 3 is a schematic representation according to embodiments herein showing a substrate carrier for holding a substrate.

FIG. 4 and FIG. 5 are schematic representation according to yet further embodiments herein showing parts of a substrate carrier for holding a substrate.

FIG. 6 is a schematic representation according to embodiments herein illustrating the directional deformation of a substrate carrier.

### DETAILED DESCRIPTION OF THE INVENTION

Reference will now be made in detail to the various embodiments, one or more examples of which are illustrated in each Fig. Each example is provided by way of explanation and is not meant as a limitation. For example, features illustrated or described as part of one embodiment can be used on or in conjunction with other embodiments to yield yet further embodiments. It is intended that the present disclosure includes such modifications and variations.

As used herein, the term “front side” of a substrate refers to the substrate's top surface, which typically faces away from the substrate carrier during processing and relates to the side that is processed, and the “backside” of a substrate refers to the substrate's bottom surface, which typically faces the substrate carrier or substrate holder during transport/processing. In embodiments described herein, the front side and backside may be substantially planar and parallel.

As used herein, the term “thermal decoupling” is intended to be understood as reducing the thermal energy transfer between two portions of the substrate carrier or between the substrate carrier and a transport device.

As used herein, the term “open cut-out” is intended to be representative of a cut-out or slit, which includes a portion that has an opening towards the side edge of the substrate carrier. As used herein, the term “closed cut-out” is intended to be representative of a cut-out or slit that is completely surrounded by the substrate carrier, e.g., a hole or breakthrough, which interconnects an upper and lower surface of the substrate carrier.

As used herein, the term “thermal processing” is intended to be representative of any processing step, which produces thermal energy. Non-limiting examples of such thermal processing may include chemical vapor deposition (CVD) such as plasma-enhanced chemical vapor deposition (PECVD) as well as physical vapor deposition (PVD) processes such as sputter deposition.

According to embodiments herein, there may be a large variety of different types of substrate holders for supporting a substrate during processing. For example, a substrate holder may include a main portion or body with a surface that receives and/or underlies the supported substrate. The surface of the substrate holder for receiving or supporting the substrate may be in contact with the backside of the supported substrate.

The main portion of the substrate carrier may, for instance, be a closed plate, which supports one or more substrates. The closed plate may include one or more recessed or thinned sections that are adapted to receive one or more substrates. The recessed or thinned sections may be dimensioned such that one substrate or a plurality of substrates may be fitted therein. In embodiments herein, the recessed or thinned sections may be referred to as depressions or pockets.

As described herein, a substrate carrier for holding a substrate to be processed is provided. The substrate carrier includes a main portion for holding the substrate, a first end portion adapted to be supported by a transport device and at least one first intermediate portion connecting the main portion with the first end portion. The at least one first intermediate portion includes one or more cut-outs adapted to reduce thermal energy transfer between the main portion and the first end portion.

According to further embodiments described herein, the main portion of the substrate carrier may be an open plate, which supports one or more substrates. The open plate may include one or more cut-outs that extend completely through the substrate carrier. The one or more cut-outs may be dimensioned such that one substrate or a plurality of substrates may be fitted therein.

In embodiments described herein, the substrate carrier may include at least a first end portion, which is adapted to be supported by a transport device. In the embodiments herein, the transport device may also be referred to as holding device. The transport device may be used to move the substrate carrier, for instance, into a processing reactor. The transport device may also function to hold or secure the substrate carrier in a predetermined position.

The first end portion of the substrate carrier may, for instance, include one or more attachment points for holding devices. For example, three attachment points may be arranged in the first end portion. The attachment points may be configured entirely as desired depending on the weight, dimension and shape of the substrate carrier. The attachment points facilitate a connection between the substrate carrier and, for instance, the transport device. According to embodiments herein, a magnet system and/or plastic parts for electric isolation may be assembled at the attachment points of the first end portion.

The substrate carrier, according to embodiments herein may optionally also include a second end portion, which is also adapted to be supported by a transport device. The second end portion may also include one or more attachment points. For instance, the second end portion may include five attachment points. According to embodiments herein, similar to the first end portion, a magnet system and/or plastic parts for electric isolation may be assembled at the attachment points of the second end portion.

The second end portion may include the same number and type of attachment points as the first end portion. In further embodiments herein, the number and type of attachment points of the second end portion may be different to the number and type of attachment points on the first end portion.

According to embodiments herein, the substrate carrier may include a first intermediate portion, which connects the main portion with the first end portion. Optionally, in embodiments described herein, the substrate carrier may include a second intermediate portion connecting the main portion with the second end portion.

In embodiments described herein, during processing, the main portion of the substrate carrier, which supports the substrate to be processed, may experience the highest temperatures. The first and/or second intermediate portions may include one or more cut-outs adapted to reduce thermal energy transfer between the main portion and the first and/or second end portion. Herein, the aforementioned cut-outs may also be referred to as thermal energy decoupling cut-outs.

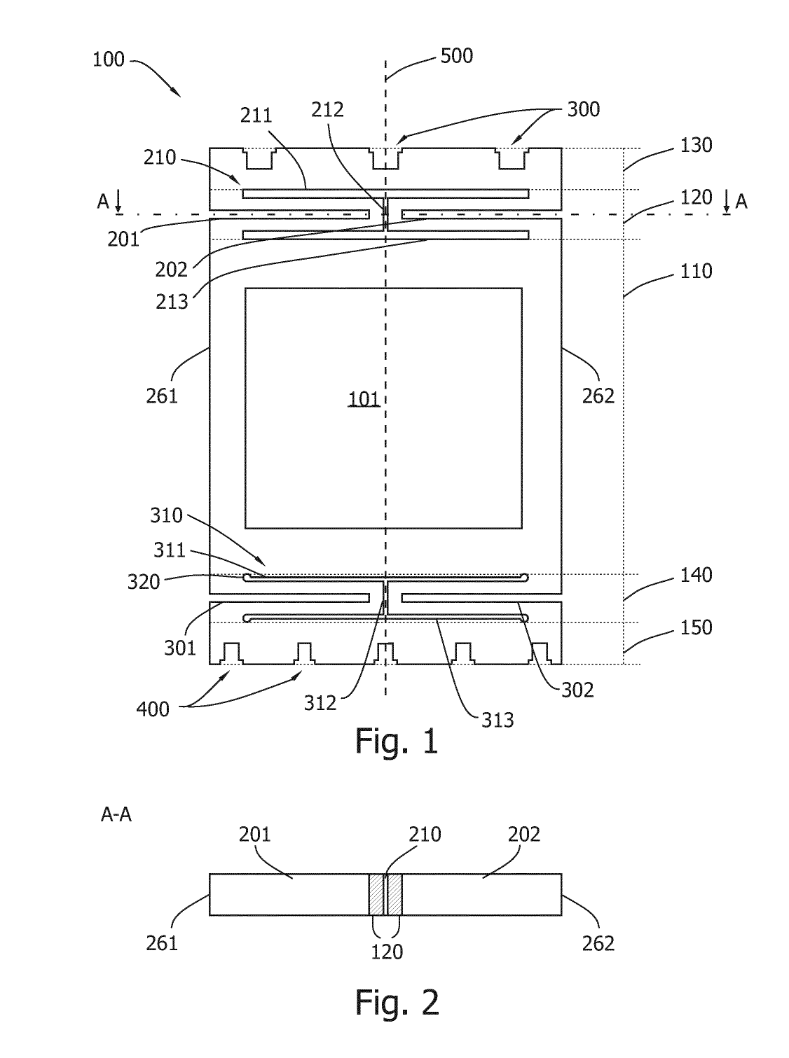

FIG. 1 is a schematic representation according to embodiments herein showing a substrate carrier 100 for holding a substrate 101. The substrate carrier may include a main portion 110 for holding the substrate 101, a first end portion 130 and a first intermediate portion 120 connecting the main portion 110 with the first end portion 130. Three attachment points 300 may be arranged in the first end portion 130 of the substrate carrier 100. The attachment points may be utilized to connect the substrate carrier to a transport device (not shown in the Figs.). The attachment points may further include a magnet system or plastic parts that provide electric isolation to the substrate carrier from, e.g., a transport device.

According to embodiments herein, the main portion of the substrate carrier may experience the greatest temperature changes during thermal load (i.e. during processing of a substrate, wherein thermal energy is provided to the substrate).

As shown in FIG. 1, the substrate carrier 100 may include a first end portion 130 arranged at a first end of the substrate carrier and a second end portion 150 arranged at a second end of the substrate carrier 100. The first end portion 130 and the second end portion 150 may be at opposite ends of the substrate carrier 100.

The main portion 110 may be interconnected to the first end portion 130 and the second end portion 150 via a first intermediate portion 120 and a second intermediate portion 140, respectively. During thermal processing of the substrate 101, which is supported in the main portion 110 of the substrate carrier 100, the highest amount of thermal energy may be localized in the main portion 110 of the substrate carrier 100.

In order to reduce the thermal energy transfer from the main portion 110 to the end portions 130, 150 of the substrate carrier 100, the first 120 and/or second 140 intermediate portions may include one or more thermal energy decoupling cut-outs.

According to embodiments herein, reducing or preventing the transmission of thermal energy from the main portion, on which a substrate is supported, to a respective end portion of a substrate carrier by one or more thermal energy decoupling cut-outs may ensure safer operation of processing systems. It may further reduce the material fatigue over time of the substrate carrier or transport device. Reducing thermal energy transmission on the substrate carrier may further reduce warping of the surface of the substrate carrier, which ensures processed substrates of an extremely high quality and further ensures that the substrate carrier may be used for consecutive processing steps without having to be replaced. Thus, the overall processing quality of substrates may be improved whilst significantly reducing the operational times and operational costs.

In order to efficiently reduce the thermal energy transfer between the main portion 110 and the first end portion 130 of the substrate carrier 100 shown in FIG. 1, the first intermediate portion 120 may include one or more thermal energy decoupling cut-outs 201, 202, 210. According to embodiments herein, the first intermediate portion 120 includes a first open cut-out 201 and a second open cut-out 202. The first cut-out 201 and the second cut-out 202 are open towards opposing side edges 261, 262 of the substrate carrier 100. Both the first cut-out 201 and the second cut-out 202 may extend towards the center of the substrate carrier 100 in a direction that is perpendicular or substantially perpendicular to the longitudinal direction of at least one of the side edges 261, 262 of the substrate carrier 100. In yet further embodiments described herein, the first and second open cut-outs may extend towards the center of the substrate carrier in a direction that is at an angle anywhere from 45° and 90° to the longitudinal direction of the respective side edges of the substrate carrier.

The first cut-out 201 and the second cut-out 202 may be arranged minor symmetric with respect to each other on the substrate carrier 100. The central plane 500 of the substrate carrier may be the plane of symmetry of the first 201 and second 202 cut-outs. Yet in further embodiments, the cut-outs may not be arranged mirror symmetric with respect to each other.

In embodiments described herein, a first open cut-out may extend from a first side edge of a substrate carrier towards a central plane of the substrate carrier and beyond that plane and a second open cut-out may extend from a second side edge of the substrate carrier towards the central plane of the substrate carrier without crossing the central plane of the substrate carrier. The second edge may be opposite to the first edge of the substrate carrier. The second open cut-out may extend in a parallel direction to the first open cut-out but the one may be offset from the other in a different plane.

According to embodiments, the first open cut-out and the second open cut-out may both extend beyond the central plane of the substrate carrier. The first open cut-out may be offset from the second open cut-out, such that the cut-outs are arranged one on top of the other along different planes. Such an arrangement of a first and second open cut-out or slit in an intermediate portion of the substrate carrier may ensure that every straight path from a main portion to a first end portion and/or from a main portion to a second end portion of the substrate carrier crosses at least one of the one or more first and/or second open cut-outs.

FIG. 2 shows a cross-section along plane A-A of the substrate carrier 100 shown in FIG. 1. According to embodiments herein, the first cut-out 201 and/or the second cut-out 202 may each extend from an outer side edge 261, 262 of the substrate carrier 100 towards the central plane 500 of the substrate carrier 100 up to 45% of the total length of the width of the substrate carrier 100. In the context thereof, the width of the substrate carrier 100 may be represented as the length of the shortest straight line from the first side edge 261 to the second side edge 262 of the substrate carrier 100.

The substrate carrier 100, according to the embodiment shown in FIG. 1, may further include a closed cut-out 210. The closed cut-out 210 may be arranged such that the length of the shortest thermally conducting path between the main portion 110 and the first end portion 130 is greater than the shortest distance between the main portion 110 and the first end portion 130.

The closed cut-out 210 may be arranged on the substrate carrier 100 such that it partially surrounds the first and second open cut-outs 201, 202, respectively. A first portion 211 of the closed cut-out 210 may be arranged above the first and second open cut-outs 201, 202. The first portion 211 may extend in a direction parallel to the first cut-out 201 and/or second cut-out 202, respectively. A second portion 212 of the closed cut-out 210 may extend in a perpendicular direction to the longitudinal direction of at least one of the open first cut-out 201 and open second cut-out 202. A third portion 213 of the closed cut-out 210 may be arranged below the first and second open cut-outs 201, 202. The third portion 213 may extend in a direction parallel to the first cut-out 201 and/or the second cut-out 202, respectively.

According to the embodiment shown in FIG. 1, the first 211, second 212 and third 213 portions of the closed cut-out 210 may work together with the first open cut-out 201 and/or the second open cut-out 202 in order to ensure that the shortest thermally conducting path between the main portion 110 and the first end portion 130 of the substrate carrier 100 is greater than the shortest distance between the main portion 110 and the first end portion 130 of the substrate carrier 100. The shortest distance between the main portion 110 and the first end portion 130 of the substrate carrier 100 may be defined as the shortest straight line between an imaginary point on the main portion 110 and an imaginary point on the first end portion 130 of the substrate carrier 100.

As described above, according to embodiments herein, the substrate carrier may include a first intermediate portion, which connects the main portion with the first end portion. Optionally, in embodiments described herein, the substrate carrier may include a second intermediate portion connecting the main portion with the second end portion.

In embodiments described herein, during processing, the main portion of the substrate carrier, which supports the substrate to be processed, may experience the highest temperatures. The first and/or second intermediate portions may include one or more cut-outs adapted to reduce thermal energy transfer between the main portion and the first and/or second end portion. Herein, the aforementioned cut-outs may also be referred to as thermal energy decoupling cut-outs.

In embodiments described herein, the one or more thermal energy decoupling cut-outs may be arranged on the substrate carrier such that the length of the shortest thermally conducting path between the main portion and the first end portion and/or between the main portion and the second end portion of the substrate carrier is greater than the shortest distance between the main portion and the first end portion and/or between the main portion and the second end portion of the substrate carrier, respectively.

According to embodiments herein, every straight path from the main portion to the first end portion and/or from the main portion to the second end portion may cross at least one of the one or more cut-outs, e.g. thermal energy decoupling cut-outs. Thereby, thermal energy from the main portion of the substrate carrier during, for instance, processing of a substrate, may be effectively decoupled or reduced from the first and/or second end portions of the substrate carrier. Advantageously, the thermal energy transfer from the substrate carrier to the one or more transport device is also decoupled or reduced.

Decoupling or reducing the thermal energy transfer from the main portion of the substrate carrier to the end portions of the substrate carrier, which ultimately decouples or reduces the thermal energy transferred from main portion to the one or more transport devices, may help to reduce material fatigue and may also allow for the use of a wider range of lighter and/or more cost efficient materials for both the one or more transport device as well as the substrate carrier.

Further, decoupling or reducing the thermal energy transfer from the main portion to the end portion(s) of the substrate carrier during thermal load may prevent warping of the substrate carrier.

In embodiments described herein, at least one of the one or more thermal energy decoupling cut-outs may be arranged such that it is completely surrounded by the substrate carrier. The term “completely surround” in the context herein may be understood as meaning that the cut-out, which extends completely through the substrate is surrounded by the substrate carrier such that the cut-out is a breakthrough, slit or perforation that extends through the substrate carrier.

According to embodiments herein, the substrate carrier or parts thereof may include metals or metal alloys, the volume of which may change upon heating, for instance, during high temperature treatment of a substrate disposed on the substrate carrier. The increase in volume of the substrate carrier during high temperature treatment of a substrate may cause warpage or distortion of the shape of the substrate carrier. Furthermore, due to temperature variations on the substrate carrier during thermal processing, differential expansion or shrinkage of the substrate carrier may lead to the warping or distortion of its surface. The substrate, disposed thereon may consequentially be damaged by such a change in shape of the surface of the substrate carrier or may render the substrate carrier un-usable for subsequent processing steps.

According to embodiments herein, the intermediate portions including the one or more thermal energy decoupling cut-outs ensure that the substrate carrier may expand and shrink during thermal processing without warping or distortion of the main portion of the substrate carrier supporting the substrate during thermal processing. Furthermore, the one or more thermal energy decoupling cut-outs of the substrate carrier may include one or more additional stress reducing cut-outs. The stress reducing cut-outs are adapted to further reduce warpage or distortion of the substrate carrier during high temperature processing.

In further embodiments described herein, the one or more stress reducing cut-outs may be interconnected or part of the one or more thermal energy decoupling cut-outs of the substrate carrier. The one or more stress reducing cut-outs may be openings that extend partially through the substrate carrier. The one or more stress reducing cut-outs may also be boreholes or breakthroughs that extend completely through the substrate carrier. According to embodiments described herein, the stress reducing cut-outs may, for instance, have a radius of curvature equal to or greater than 2 mm, e.g., anywhere from 2 mm to 25 mm.

In embodiments described herein, each of the thermal energy decoupling cut-outs may include one or more stress reducing cut-outs. For instance, a thermal energy decoupling cut-out that is completely surrounded by the substrate carrier may include four stress reducing cut-outs.

Similar to the first end portion 130, the second end portion 150 of the substrate carrier 100 may include one or more attachment points 400, which may be utilized to connect the substrate carrier 100 to a transport device (not shown in the Figs.). The five attachment points of the second end portion of the substrate carrier shown in FIG. 1 may include a magnet system or plastic parts that provide electric isolation to the substrate carrier from, e.g., a transport device. In yet further embodiments herein, the substrate carrier may include a different number of attachment points. The number of attachment points may, for instance, be dependent on the type of transport device with which the substrate carrier is used. According to embodiments herein, the number of attachment points of the first end portion 130 may be the same or different than the number of attachment points of the second end portion 150 of the substrate carrier 100.

According to the embodiment shown in FIG. 1, the main portion 110 may be connected to the second end portion 150 via a second intermediate portion 140. Similar to the first intermediate portion 120, the second intermediate portion 140 of the substrate carrier 100 may include one or more thermal energy decoupling cut-outs 301, 302, 310, which may also be arranged in a similar manner as the cut-outs 201, 202 and 210 of the first intermediate portion 120.

The first open cut-out 301 and second open cut-out 302 of the second intermediate portion 140 may be open towards opposing side edges 261, 262 of the substrate carrier 100. Both the first cut-out 301 and the second cut-out 302 may extend towards the center of the substrate carrier 100 in a direction that is perpendicular or substantially perpendicular to the longitudinal direction of at least one of the side edges 261, 262 of the substrate carrier 100. In yet further embodiments described herein, the first and second cut-outs may extend towards the center of the substrate carrier in a direction that is at an angle anywhere between 45° and 90° to the longitudinal direction of the respective side edges of the substrate carrier.

The first cut-out 301 and the second cut-out 302 may be arranged minor symmetric with respect to each other on the substrate carrier 100. Central plane 500 of the substrate carrier may be the plane of symmetry of the first 301 and second 302 cut-outs. Yet in further embodiments, the cut-outs may not be arranged mirror symmetric with respect to each other. For example, a first cut-out may extend from a first side edge of the substrate carrier beyond the central plane 500 of the substrate carrier.

In embodiments described herein, a first open cut-out of the second intermediate portion may extend from a first side edge of a substrate carrier towards a central plane of the substrate carrier and beyond that plane and a second open cut-out may extend from a second side edge of the substrate carrier towards the central plane of the substrate carrier without crossing the central plane of the substrate carrier. The second edge may be opposite to the first edge of the substrate carrier. The second open cut-out may extend in a parallel direction to the first open cut-out but the one may be offset from the other in a different plane.

According to embodiments, the first open cut-out and the second open cut-out may both extend beyond the central plane of the substrate carrier. The first open cut-out may be offset from the second open cut-out, such that the cut-outs are arranged one on top of the other along different planes. Such an arrangement of a first and second open cut-out or slit in an intermediate portion of the substrate carrier may ensure that every straight path from a main portion to a first end portion and/or from a main portion to a second end portion of the substrate carrier crosses at least one of the one or more first and/or second open cut-outs.

The second intermediate portion 140 of the substrate carrier 100, according to the embodiment shown in FIG. 1, may include a closed cut-out 310 arranged similar to the closed cut-out 210 of the first intermediate portion 120. The closed cut-out 310 may be arranged such that the length of the shortest thermally conducting path between the main portion 110 and the second end portion 150 is greater than the shortest distance between the main portion 110 and the second end portion 150.

The closed cut-out 310 may be arranged on the substrate carrier 100 such that it partially surrounds the first and second open cut-outs 301, 302, respectively. A first portion 311 of the closed cut-out 310 may be arranged above the first and second open cut-outs 301, 302. The first portion 311 may extend in a direction parallel to the first cut-out 301 and/or second cut-out 302, respectively. A second portion 312 of the closed cut-out 310 may extend in a perpendicular direction to the longitudinal direction of at least one of the open first cut-out 301 and open second cut-out 302. A third portion 313 of the closed cut-out 310 may be arranged below the first and second open cut-outs 301, 302. The third portion 313 may extend in a direction parallel to the first cut-out 301 and/or the second cut-out 302, respectively.

According to the embodiment shown in FIG. 1, the first 311, second 312 and third 313 portions of the closed cut-out 310 may work together with the first open cut-out 301 and/or the second open cut-out 302 in order to ensure that the shortest thermally conducting path between the main portion 110 and the second end portion 150 of the substrate carrier 100 is greater than the shortest distance between the main portion 110 and the second end portion 150 of the substrate carrier 100. The shortest distance between the main portion 110 and the second end portion 150 of the substrate carrier 100 may be defined as the shortest straight line between an imaginary point on the main portion 110 and an imaginary point on the second end portion 150 of the substrate carrier 100.

The closed cut-out 310 of the second intermediate portion 140 of the substrate carrier 100 shown in FIG. 1 may include one or more stress reducing cut-outs 320. The closed cut-out 310 of the second intermediate portion 140 includes four stress reducing cut-outs. Two of the stress reducing cut-outs are arranged in the first portion 311 of the closed cut-out 310. The other two stress reducing cut-outs are arranged in the third portion 313 of the closed cut-out 310. In the embodiments herein, the stress reducing cut-outs 320 may be arranged at opposite ends of the first portion 311 and the third portion 313 of the closed cut-out 310, respectively.

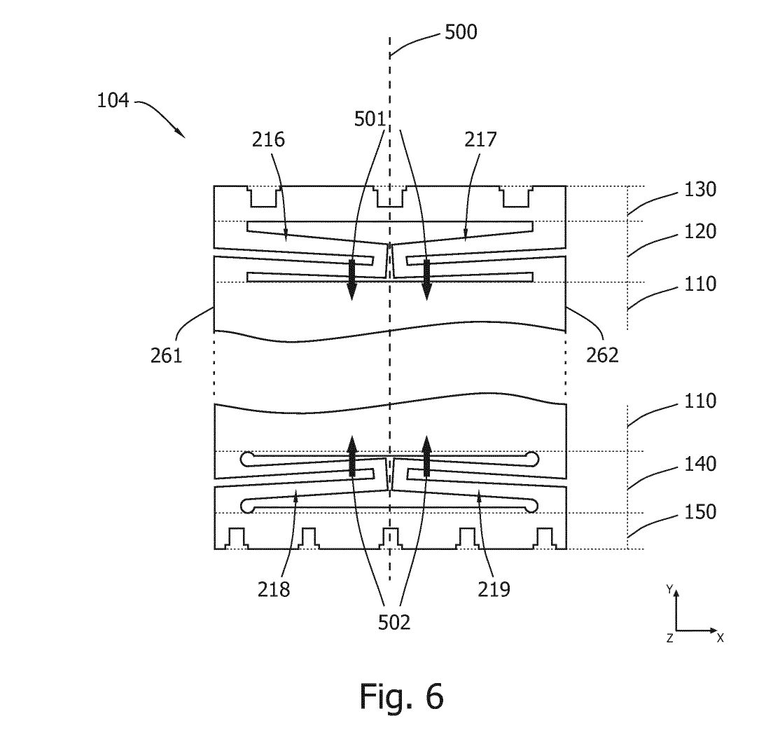

According to embodiments herein, the closed cut-outs of both the first and second intermediate portions of the substrate carrier may include one or more stress reducing cut-outs. These stress reducing cut-outs may have a radius of curvature equal to or greater than 2 mm, e.g., anywhere from 2 mm to 25 mm. The stress reducing cut-outs in embodiments described herein may facilitate a relative movement of the portion of the substrate carrier which is arranged between the closed cut-out and the open cut-out with respect to the main and/or end portions of the substrate carrier (e.g. see FIG. 6 and the description thereof below).

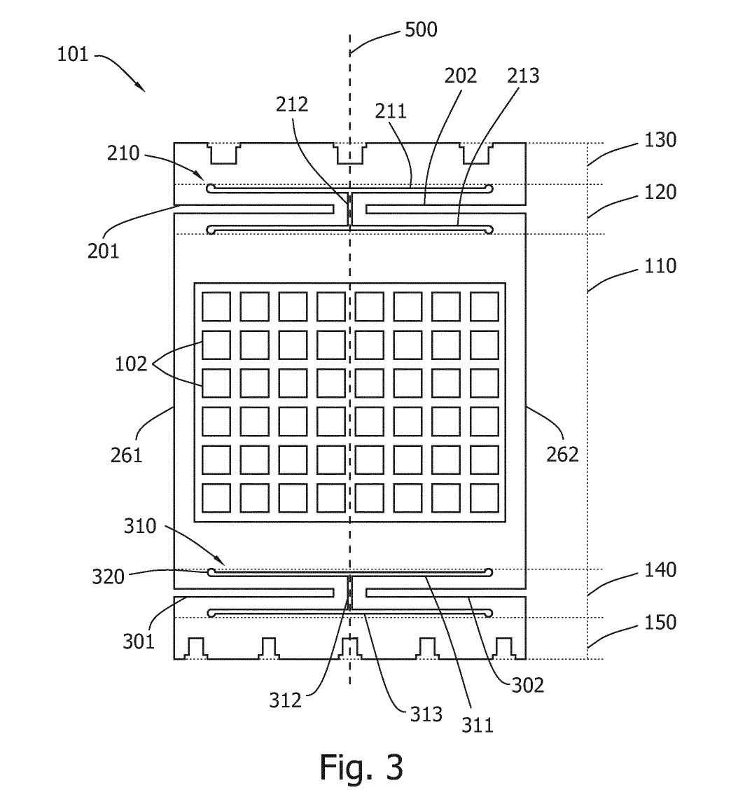

FIG. 3 shows a substrate carrier 101 according to a further embodiment herein. The substrate carrier 101 includes a main portion 110 with a plurality of cut-outs 102 adapted to receive a plurality of substrates. The plurality of cut-outs 102 may be thinned sections, depressions or breakthroughs extending completely through the substrate carrier 101.

The main portion 110 may be interconnected to the first end portion 130 and the second end portion 150 via a first intermediate portion 120 and a second intermediate portion 140, respectively. During thermal processing of the plurality of substrates, which are supported in the main portion 110 of the substrate carrier 101, the highest amount of thermal energy may be localized in the main portion 110 of the substrate carrier 101.

Similar to the embodiment shown in FIG. 1, in order to reduce the thermal energy transfer from the main portion 110 to the end portions 130, 150 of the substrate carrier 101, the first 120 and/or second 140 intermediate portions may include one or more thermal energy decoupling cut-outs. The first end portion 130 and the second end potion 150 of the substrate carrier 101 may be connected with the main portion 110 via a first 120 and a second 140 intermediate portion, respectively. The first 120 and second 140 intermediate portions may include both one or more thermal energy decoupling cut-outs and one or more stress reducing cut-outs.

In the embodiment shown in FIG. 3, the first intermediate portion 120 includes two open thermal energy decoupling cut-outs arranged mirror symmetric with respect to each other. The first intermediate portion 120 further includes a closed thermal energy decoupling cut-out that partially surrounds the two open thermal energy decoupling cut-outs.

In order to efficiently reduce the thermal energy transfer between the main portion 110 and the first end portion 130 of the substrate carrier 101 shown in FIG. 3, the first intermediate portion 120 may include one or more thermal energy decoupling cut-outs 201, 202, 210. According to embodiments herein, the first intermediate portion 120 includes a first open cut-out 201 and a second open cut-out 202. The first cut-out 201 and the second cut-out 202 are open towards opposing side edges 261, 262 of the substrate carrier 101. Both the first cut-out 201 and the second cut-out 202 may extend towards the center of the substrate carrier 101 in a direction that is perpendicular or substantially perpendicular to the longitudinal direction of at least one of the side edges 261, 262 of the substrate carrier 101. In yet further embodiments described herein, the first and second open cut-outs may extend towards the center of the substrate carrier in a direction that is at an angle anywhere between 45° and 90° to the longitudinal direction of the respective side edges of the substrate carrier.

The first cut-out 201 and the second cut-out 202 may be arranged minor symmetric with respect to each other on the substrate carrier 101. The central plane 500 of the substrate carrier may be the plane of symmetry of the first 201 and second 202 cut-outs. Yet in further embodiments, the cut-outs may not be arranged minor symmetric with respect to each other.

The substrate carrier 101 according to the embodiment shown in FIG. 3, may further include a closed cut-out 210. The closed cut-out 210 may be arranged such that the length of the shortest thermally conducting path between the main portion 110 and the first end portion 130 is greater than the shortest distance between the main portion 110 and the first end portion 130.

The closed cut-out 210 may be arranged on the substrate carrier 101 such that it partially surrounds the first and second open cut-outs 201, 202, respectively. A first portion 211 of the closed cut-out 210 may be arranged above the first and second open cut-outs 201, 202. The first portion 211 may extend in a direction parallel to the first cut-out 201 and/or second cut-out 202, respectively. A second portion 212 of the closed cut-out 210 may extend in a perpendicular direction to the longitudinal direction of at least one of the open first cut-out 201 and open second cut-out 202. A third portion 213 of the closed cut-out 210 may be arranged below the first and second open cut-outs 201, 202. The third portion 213 may extend in a direction parallel to the first cut-out 201 and/or the second cut-out 202, respectively.

According to the embodiment shown in FIG. 3, the first 211, second 212 and third 213 portions of the closed cut-out 210 may work together with the first open cut-out 201 and/or the second open cut-out 202 in order to ensure that the shortest thermally conducting path between the main portion 110 and the first end portion 130 of the substrate carrier 101 is greater than the shortest distance between the main portion 110 and the first end portion 130 of the substrate carrier 101. The shortest distance between the main portion 110 and the first end portion 130 of the substrate carrier 101 may be defined as the shortest straight line between an imaginary point on the main portion 110 and an imaginary point on the first end portion 130 of the substrate carrier 101.

The closed cut-out 210 of the first intermediate portion 120 of the substrate carrier 101 shown in FIG. 3 may include one or more stress reducing cut-outs 220. The closed cut-out 210 of the first intermediate portion 120 includes four stress reducing cut-outs. Two of the stress reducing cut-outs are arranged in the first portion 211 of the closed cut-out 210. The other two stress reducing cut-outs are arranged in the third portion 213 of the closed cut-out 210. In the embodiments herein, the stress reducing cut-outs 220 may be arranged at opposite ends of the first portion 211 and the third portion 213 of the closed cut-out 210, respectively.

According to embodiments herein, the closed cut-outs of the first intermediate portion of the substrate carrier may include one or more stress reducing cut-outs. These stress reducing cut-outs may have a radius of curvature equal to or greater than 2 mm, e.g., anywhere from 2 mm to 25 mm. The stress reducing cut-outs in embodiments described herein may facilitate a relative movement of the portion of the substrate carrier which is arranged between the closed cut-out and the open cut-out with respect to the main and/or end portions of the substrate carrier (e.g. see FIG. 6 and the description thereof below).

According to the embodiment shown in FIG. 3, the main portion 110 may be connected to the second end portion 150 via a second intermediate portion 140. Similar to the first intermediate portion 120, the second intermediate portion 140 of the substrate carrier 101 may include one or more thermal energy decoupling cut-outs 301, 302, 310, which may also be arranged in a similar manner as the cut-outs 201, 202 and 210 of the first intermediate portion 120.

The first open cut-out 301 and second open cut-out 302 of the second intermediate portion 140 may be open towards opposing side edges 261, 262 of the substrate carrier 101. Both the first cut-out 301 and the second cut-out 302 may extend towards the center of the substrate carrier 101 in a direction that is perpendicular or substantially perpendicular to the longitudinal direction of at least one of the side edges 261, 262 of the substrate carrier 101. In yet further embodiments described herein, the first and second cut-outs may extend towards the center of the substrate carrier in a direction that is at an angle anywhere between 45° and 90° to the longitudinal direction of the respective side edges of the substrate carrier.

The first cut-out 301 and the second cut-out 302 may be arranged minor symmetric with respect to each other on the substrate carrier 101. Central plane 500 of the substrate carrier may be the plane of symmetry of the first 301 and second 302 cut-outs. Yet in further embodiments, the cut-outs may not be arranged mirror symmetric with respect to each other. For example, a first cut-out may extend from a first side edge of the substrate carrier beyond the central plane 500 of the substrate carrier.

In embodiments described herein, a first open cut-out may extend from a first side edge of a substrate carrier towards a central plane of the substrate carrier and beyond that plane and a second open cut-out may extend from a second side edge of the substrate carrier towards the central plane of the substrate carrier without crossing the central plane of the substrate carrier. The second edge may be opposite to the first edge of the substrate carrier. The second open cut-out may extend in a parallel direction to the first open cut-out but the one may be offset from the other in a different plane.

According to embodiments, the first open cut-out and the second open cut-out may both extend beyond the central plane of the substrate carrier. The first open cut-out may be offset from the second open cut-out, such that the cut-outs are arranged one on top of the other along different planes. Such an arrangement of a first and second open cut-out or slit in an intermediate portion of the substrate carrier may ensure that every straight path from a main portion to a first end portion and/or from a main portion to a second end portion of the substrate carrier crosses at least one of the one or more first and/or second open cut-outs.

The second intermediate portion 140 of the substrate carrier 101, according to the embodiment shown in FIG. 3, may include a closed cut-out 310 arranged similar to the closed cut-out 210 of the first intermediate portion 120. The closed cut-out 310 may be arranged such that the length of the shortest thermally conducting path between the main portion 110 and the second end portion 150 is greater than the shortest distance between the main portion 110 and the second end portion 150.

The closed cut-out 310 may be arranged on the substrate carrier 101 such that it partially surrounds the first and second open cut-outs 301, 302, respectively. A first portion 311 of the closed cut-out 310 may be arranged above the first and second open cut-outs 301, 302. The first portion 311 may extend in a direction parallel to the first cut-out 301 and/or second cut-out 302, respectively. A second portion 312 of the closed cut-out 310 may extend in a perpendicular direction to the longitudinal direction of at least one of the open first cut-out 301 and open second cut-out 302. A third portion 313 of the closed cut-out 310 may be arranged below the first and second open cut-outs 301, 302. The third portion 313 may extend in a direction parallel to the first cut-out 301 and/or the second cut-out 302, respectively.

According to the embodiment shown in FIG. 3, the first 311, second 312 and third 313 portions of the closed cut-out 310 may work together with the first open cut-out 301 and/or the second open cut-out 302 in order to ensure that the shortest thermally conducting path between the main portion 110 and the second end portion 150 of the substrate carrier 101 is greater than the shortest distance between the main portion 110 and the second end portion 150 of the substrate carrier 101. The shortest distance between the main portion 110 and the second end portion 150 of the substrate carrier 101 may be defined as the shortest straight line between an imaginary point on the main portion 110 and an imaginary point on the second end portion 150 of the substrate carrier 101.

The closed cut-out 310 of the second intermediate portion 140 of the substrate carrier 101 shown in FIG. 1 may include one or more stress reducing cut-outs 320. The closed cut-out 310 of the second intermediate portion 140 may, for instance, include four stress reducing cut-outs. Two of the stress reducing cut-outs may be arranged in the first portion 311 of the closed cut-out 310. The other two stress reducing cut-outs may be arranged in the third portion 313 of the closed cut-out 310. In the embodiments herein, the stress reducing cut-outs 320 may be arranged at opposite ends of the first portion 311 and the third portion 313 of the closed cut-out 310, respectively.

According to embodiments herein, these stress reducing cut-outs may have a radius of curvature equal to or greater than 2 mm, e.g., anywhere from 2 mm to 25 mm. The stress reducing cut-outs in embodiments described herein may facilitate a relative movement of the portion of the substrate carrier which is arranged between the closed cut-out and the open cut-out with respect to the main and/or end portions of the substrate carrier (e.g. see FIG. 6 and the description thereof below).

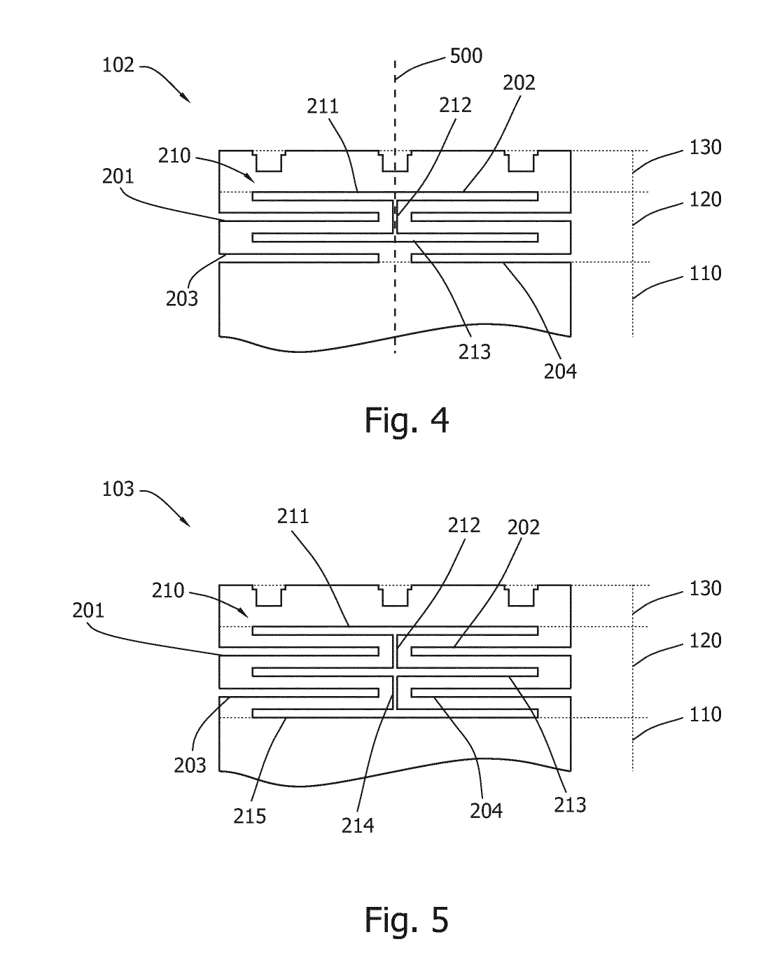

FIG. 4 and FIG. 5 are schematic representation according to yet further embodiments described herein showing parts of a substrate carrier for holding a substrate. Part of the substrate carrier 102 shown in FIG. 4 shows part of a main portion 110, an intermediate portion 120 that connects the main portion 110 with an end portion 130 the substrate carrier 102.

In order to reduce the thermal energy transfer from the main portion 110 to the end portions 130 during thermal processing of a substrate, the intermediate portions 120 may include one or more thermal energy decoupling cut-outs and optionally one or more stress reducing cut-outs.

According to the embodiment shown in FIG. 4, the first intermediate portion 120 includes a first open cut-out 201, a second open cut-out 202, a third open cut-out 203 and a fourth open cut-out 204. The first 201 and second 202 cut-outs may be open towards opposing side edges 261, 262 of the substrate carrier 102. Similarly, the third 203 and fourth 204 cut-outs may also be open towards opposing side edges 261, 262 of the substrate carrier 102. The first 201, second 202, third 203 and fourth 204 cut-out may extend towards the center of the substrate carrier 102 in a direction that is perpendicular or substantially perpendicular to the longitudinal direction of at least one of the side edges 261, 262 of the substrate carrier 102. In yet further embodiments described herein, the first, second, third and fourth open cut-outs may extend towards the center of the substrate carrier in a direction that is at an angle anywhere between 45° and 90° to the longitudinal direction of the respective side edges of the substrate carrier.

The first 201 and second 202 cut-outs as well as the third 203 and fourth 204 cut-outs may be arranged mirror symmetric with respect to each other on the substrate carrier 102, respectively. The central plane 500 of the substrate carrier may be the plane of symmetry of the first 201 and second 202 cut-outs as well as of the third 203 and fourth 204 cut-outs, respectively. Yet in further embodiments, the cut-outs may not be arranged minor symmetric with respect to each other.

In embodiments described herein, a first open cut-out may extend from a first side edge of a substrate carrier towards a central plane of the substrate carrier and beyond that plane and a second open cut-out may extend from a second side edge of the substrate carrier towards the central plane of the substrate carrier without crossing the central plane of the substrate carrier. The second edge may be opposite to the first edge of the substrate carrier. The second open cut-out may extend in a parallel direction to the first open cut-out but the one may be offset from the other in a different plane. A third and fourth open cut-out may be arranged in a similar fashion to the first and second cut-outs.

According to embodiments, the first and second open cut-outs and/or the third and fourth open cutouts may extend beyond the central plane of the substrate carrier. The first open cut-out may be offset from the second open cut-out and the third open cut-out may be offset from the fourth cut-out, such that the cut-outs are arranged one on top of the other along different planes. Such an arrangement of a first, second, third and fourth open cut-out or slit in an intermediate portion of the substrate carrier may ensure that every straight path from a main portion to a first end portion and/or from a main portion to a second end portion of the substrate carrier crosses at least one of the one or more open cut-outs.

The substrate carrier 102, according to the embodiment shown in FIG. 4, may further include a closed cut-out 210. The closed cut-out 210 may be arranged such that the length of the shortest thermally conducting path between the main portion 110 and the first end portion 130 is greater than the shortest distance between the main portion 110 and the first end portion 130.

The closed cut-out 210 may be arranged on the substrate carrier 102 such that it partially surrounds the first 201, second 202, third 203 and fourth 204 open cut-outs, respectively. A first portion 211 of the closed cut-out 210 may be arranged above the first 201 and second 202 open. The first portion 211 may extend in a direction parallel to the first cut-out 201 and/or second cut-out 202, respectively. A second portion 212 of the closed cut-out 210 may extend in a perpendicular direction to the longitudinal direction of at least one of the open first cut-out 201 and open second cut-out 202. A third portion 213 of the closed cut-out 210 may be arranged below the first 201 and second 202 open cut-outs, and above the third 203 and fourth 204 open cut-outs, respectively. The third portion 213 of the closed cut-out 210 may extend in a direction parallel to any one or more of the first 201, second 202, third 203 and fourth 204 open cut-outs, respectively.

According to the embodiment shown in FIG. 4, the first 211, second 212 and third 213 portions of the closed cut-out 210 may work together with any one of the first 201, second 202, third, 203 and fourth 204 open cut-outs in order to ensure that the shortest thermally conducting path between the main portion 110 and the first end portion 130 of the substrate carrier 102 is greater than the shortest distance between the main portion 110 and the first end portion 130 of the substrate carrier 102. The shortest distance between the main portion 110 and the first end portion 130 of the substrate carrier 102 may be defined as the shortest straight line between an imaginary point on the main portion 110 and an imaginary point on the first end portion 130 of the substrate carrier 102.

The closed cut-out 210 of the first intermediate portion 120 of the substrate carrier 102 shown in FIG. 4 may optionally include one or more stress reducing cut-outs (not shown in the Fig.). The closed cut-out 210 of the first intermediate portion 120 includes four stress reducing cut-outs. Two of the stress reducing cut-outs may be arranged in the first portion 211 of the closed cut-out 210. The other two stress reducing cut-outs shown in FIG. 4 may be arranged in the third portion 213 of the closed cut-out 210. In the embodiments herein, the stress reducing cut-outs 220 may be arranged at opposite ends of the first portion 211 and the third portion 213 of the closed cut-out 210, respectively.

According to embodiments herein, the closed cut-outs of the first intermediate portion of the substrate carrier may include one or more stress reducing cut-outs. These stress reducing cut-outs may have a radius of curvature equal to or greater than 2 mm, e.g., anywhere from 2 mm to 25 mm. The stress reducing cut-outs in embodiments described herein may facilitate a relative movement of the portion of the substrate carrier which is arranged between the closed cut-out and the open cut-out with respect to the main and/or end portions of the substrate carrier (e.g. see FIG. 6 and the description thereof below).

FIG. 5 shows part of a substrate carrier according to a further embodiment herein. The part of a substrate carrier 103 shown in FIG. 5 resembles the part of the substrate carrier 102 shown in FIG. 4. The difference between these embodiments being that the closed cut-out 210 of the embodiment shown in FIG. 5 includes an additional fourth portion 214 and fifth portion 215. The fourth portion 214 of the closed cut-out 210 may extend in a perpendicular direction to the longitudinal direction of at least one of the open third cut-out 203 and open fourth cut-out 204. The fifth portion 215 of the closed cut-out 210 may be arranged below the third 203 and fourth 204 open cut-outs. The fifth portion 215 of the closed cut-out 210 may extend in a direction parallel to any one or more of the first 201, second 202, third 203 and fourth 204 open cut-outs, respectively.

According to embodiments herein, the additional fourth and fifth portions of the closed cut-out may increase the thermal decoupling effect between the main portion and end portion(s) of a substrate carrier. In other words, the fourth and fifth portions of the closed cut-out may increase the shortest thermal conducting path between the main portion and the end portion(s) of a substrate carrier compared to embodiments where the closed cut-out only includes a first, a second and third portion (e.g. see FIG. 4). Yet, in embodiments described herein, the total number of portions of the closed cut-out may vary anywhere from three to fifteen. Similar to any of the previous embodiments described herein, the closed cut-out shown in FIG. 4 and FIG. 5 may further include one or more stress reducing cut-outs as described above.

FIG. 6 shows the directional deformation of a substrate carrier according to embodiments described herein. The directional deformation shown in FIG. 6 is magnified to better illustrate the displacement of the thermally conductive path portions of the first 120 and second 140 intermediate portions of the substrate carrier 104. The actual deformation depends on various parameters such as, for instance, the processing temperature, the material and length of the carrier. The thermally conductive path portions 216, 217 of the first intermediate portion 120, which extends towards a central plane 500 of the substrate carrier 104, may move in a direction towards the main portion 110 of the substrate carrier 104. The sections of the thermally conductive path portions 216, 217, 218, 219 closest to the central plane 500 of the substrate carrier 104 may experience a greater displacement than the sections of the thermally conductive path portions 216, 217, 218, 219 that are closer to a side edge 261, 262 of the substrate carrier 104.

According to embodiments herein, during thermal processing the sections of the thermally conductive path portions 216, 217 of the first intermediate section 120 closest to a central plane 500 of the substrate carrier 104 may move downwards towards the main portion 110 of the substrate carrier 104 when the thermal expansion in the main portion 110 is larger than at the end portion 130 of the substrate carrier 104. Similarly, the sections of the thermally conductive path portions 218, 219 of the second intermediate portion 140 closest to a central plane 500 of the substrate carrier 104 may move downwards towards the main portion 110 of the substrate carrier 104 when the thermal expansion in the main portion 110 is larger than at the end portion 150 of the substrate carrier 104. This freedom to move of the thermally conductive path portions may prevent the out of plane bending or warping of the substrate carrier.

In embodiments herein, the substrate carrier including the one or more thermal energy decoupling cut-outs and optionally the one or more stress reducing cut-outs may be used to reduce the thermal energy transfer between a substrate and a transport device whilst the substrate held by the substrate carrier undergoes thermal processing.

Exemplary embodiments of systems for processing substrates and substrate carriers are described above in detail. The systems and substrate carriers are not limited to the specific embodiments described herein, but rather, components of the systems and substrate carriers may be utilized independently and separately from other components described herein.

Although specific features of various embodiments of the invention may be shown in some drawings and not in others, this is for convenience only. In accordance with the principles of the invention, any feature of a drawing may be referenced or claimed in combination with any feature of any other drawing.

This written description uses examples to disclose the invention, including the best mode, and also to enable any person skilled in the art to practice the invention, including making and using any devices or systems and performing any incorporated methods. While various specific embodiments have been disclosed in the foregoing, those skilled in the art will recognize that the spirit and scope of the claims allows for equally effective modifications. Especially, mutually non-exclusive features of the embodiments described above may be combined with each other. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

1. A substrate carrier for holding a substrate to be processed and for transporting the substrate in or through a processing area with a transport device, the substrate carrier comprising:
a main portion for holding the substrate;
a first end portion adapted to be supported by the transport device; and
at least one first intermediate portion connecting the main portion with the first end portion, wherein the at least one first intermediate portion includes one or more cut-outs adapted to reduce thermal energy transfer between the main portion and the first end portion.

2. The substrate carrier of claim 1, further comprising at least one second intermediate portion located between the main portion and a second end portion adapted to be supported by the transport device.

3. The substrate carrier according to claim 1, wherein the length of the shortest thermally conducting path between the main portion and the first end portion is greater than the shortest distance between the main portion and the first end portion.

4. The substrate carrier according to claim 1, wherein every straight path from the main portion to the first end portion crosses at least one of the one or more cut-outs.

5. The substrate carrier according to claim 1, wherein at least one of the one or more cut-outs is completely surrounded by the substrate carrier.

6. The substrate carrier according to claim 1, wherein at least one of the one or more cut-outs is arranged such that the total length of an outer side edge of the at least one first intermediate portion is greater than the length of a straight line parallel to an outer side edge of the substrate carrier, along the outer side edge of the first intermediate portion.

7. The substrate carrier according to claim 1, wherein the at least one first intermediate portion comprises two or more cut-outs.

8. The substrate carrier according to claim 1, wherein the at least one first intermediate portion comprises one or more stress reducing cut-outs.

9. The substrate carrier according to claim 8, wherein the one or more stress reducing cut-outs are part of the one or more cut-outs adapted to reduce thermal energy transfer between the main portion and the first end portion.

10. The substrate carrier according to claim 8, wherein the one or more stress reducing cut-outs have a radius of curvature greater than 2 mm.

11. The substrate carrier according to claim 1, wherein the one or more cut-outs extend completely through the substrate carrier.

12. The substrate carrier according to claim 2, wherein the first end portion and the second end portion are at opposite ends of the substrate carrier.

13. Use of the substrate carrier according to claim 1 for reducing the thermal energy transfer between the substrate and the transport device whilst the substrate held by the substrate carrier is undergoing thermal processing.

14. A system for processing a substrate comprising:
a substrate carrier for holding a substrate to be processed and for transporting the substrate in or through a processing area with a transport device, the substrate carrier comprising:
a main portion for holding the substrate;
a first end portion adapted to be supported by the transport device; and
at least one first intermediate portion connecting the main portion with the first end portion, wherein the at least one first intermediate portion includes one or more cut-outs adapted to reduce thermal energy transfer between the main portion and the first end portion;
at least one processing chamber for processing the substrate; and
a transport device for supporting the substrate carrier.

15. The system of claim 14, wherein the system is a vacuum deposition system.

16. The substrate carrier according to claim 2, wherein the at least one second intermediate portion includes one or more cut-outs adapted to reduce thermal energy transfer between the main portion and the second end portion.

17. The substrate carrier according to claim 2, wherein every straight path from the main portion to the first end portion and from the main portion to the second end portion crosses at least one of the one or more cut-outs.

18. The substrate carrier according to claim 2, wherein the at least one first intermediate portion and the at least one second intermediate portion comprise two or more cut-outs.

19. The substrate carrier according to claim 2, wherein the at least one first intermediate portion and the at least one second intermediate portion comprise one or more stress reducing cut-outs.

20. The substrate carrier according to claim 11, wherein the one or more stress reducing cut-outs extend completely through the substrate carrier.
